(19) United States
(12) Patent Application Publication
(10) Pub. No.: US 2026/0333562 A1
(43) Pub. Date: Oct. 22, 2026

(54) CONNECTOR FOR A PRINTED CIRCUIT FORMING A HEAT SINK AND CONFIGURED TO ALLOW AN ELECTRICAL AND MECHANICAL CONNECTION

(71) Applicant: VALEO SYSTEMES THERMIQUES, Le Mesnil-Saint-Denis (FR)

(72) Inventors: Anthony Brisset, Le Mesnil Saint Denis (FR); Benoit Derouane, Le Mesnil Saint Denis (FR); Philippe Mercier, Le Mesnil Saint Denis (FR); Thomas Koumpogiannis, Le Mesnil Saint Denis (FR); Hedi Krifa, Le Mesnil Saint Denis (FR)

(73) Assignee: VALEO SYSTEMES THERMIQUES, Le Mesnil-Saint-Denis (FR)

(21) Appl. No.: 19/122,072

(22) PCT Filed: Oct. 10, 2023
(86) PCT No.: PCT/EP2023/078066

§ 371 Date: Apr. 17, 2025

(30) Foreign Application Priority Data
Oct. 18, 2022 (FR) 2210761

(51) Int. Cl. H05K 1/02; H01R 12/70; H01R 12/71; H02K 11/33; H05K 1/184

(52) U.S. Cl. CPC H05K 1/0201; H01R 12/7082; H01R 12/714; H02K 11/33; H05K 1/184; H02K 2211/03; H05K 2201/066; H05K 2201/10189

(57) ABSTRACT

A connector for a printed circuit, the connector includes: a pin which extends longitudinally along a main axis; and a connector head which is attached to one end of the pin and extends in a plane perpendicular to the main axis of the pin. The head includes at least three tabs which each extend along a secondary longitudinal axis parallel to the main axis of the pin. The tabs all extend from a single side of the connector head such that the tabs, as well as the pin, are configured to pass through the printed circuit. The connector is made of a metal so as to form a heat sink for the printed circuit.

### TECHNICAL FIELD

The present invention relates to a connector for a printed circuit board. The invention also relates to the printed circuit board comprising at least one of said connectors, and to a three-phase motor comprising said printed circuit board.

The invention relates to the technical field of motor vehicles, and more particularly to three-phase motors of motor vehicles comprising a printed circuit board with connectors.

### PRIOR ART

Motor vehicles generally comprise an engine with a cooling system that is essential for the thermal regulation of said engine. In a present-day vehicle, this cooling system comprises at least one circulation circuit in which a coolant flows, said circuit being positioned in contact with the engine. As the coolant heats up, it will lower the temperature of the engine through heat exchange. When the temperature of the coolant reaches a threshold value, generally at least 90 °C, a fan is triggered in order to lower the temperature of said coolant below the threshold value.

The fan of the engine comprises at least one blower wheel driven by a three-phase motor. Such a motor is controlled by virtue of a printed circuit board. This printed circuit board comprises electrical and/or electronic components, which can trigger various functions within the motor. Some of these components, referred to as power components, produce a significant amount of heat, which can lead to premature degradation of said components if it is not properly dissipated.

In addition, a mechanical connection has to be established between the motor and the printed circuit board, generally using pins. It is also known that these pins can form all or part of a connector for a printed circuit board, it therefore being possible for such a connector to be used for the electrical connection between the electric motor and the printed circuit board.

One example of such a connector is described in published patent document US 2013/0342986 A1. This document discloses a connector with a pin that extends along a main axis, and a connector head positioned at one of the ends of the pin. Three tabs extend from the head of the connector and are arranged along an axis parallel to the main axis, on the opposite side to the pin. However, holding the connector using the three tabs makes the electrical connection between the head and the circuit board fragile and easily breakable.

The aim of the invention is to overcome at least one of the drawbacks of the abovementioned prior art. More particularly, the aim of the invention is to promote thermal transfer between the power components mounted on the printed circuit board and the connector, while at the same time enabling an electrical and mechanical connection between the printed circuit board and the motor.

Another aim of the application is to enable better stability of the connector when it is mounted on the printed circuit board.

### DISCLOSURE OF THE INVENTION

The solution proposed by the invention is a connector for a printed circuit board, the connector being configured to enable an electrical connection to a motor, the connector comprising: a pin extending longitudinally along a main axis, and a connector head, which is attached to one end of the pin and extends in a plane that is perpendicular to said main axis of the pin, the head comprising at least three tabs each extending along a secondary longitudinal axis parallel to the main axis of the pin, the tabs all extending from the same side of the connector head so that said tabs, as well as the pin, are configured to pass through the printed circuit board, and the connector is made of a metal so as to form a heat sink for the printed circuit board.

The connector according to the invention performs three functions within the motor. First of all, it enables the heat produced by the power components to be dissipated from the head to the pin of the connector. This function is improved by the shape of the connector and by its being manufactured from metal. The larger the head of the connector, the more efficient the heat dissipation is.

Secondly, the connector enables the mechanical connection between the printed circuit board and the motor. This connection is improved by the pin and the tabs being positioned on a single side of the head of the connector, thereby improving the stability of said connector after it has been inserted into the printed circuit board. This stability is also particularly important when the components and the connectors are placed on the printed circuit board, and before they are soldered. Specifically, incorrect placement of the components could impede soldering thereof and lead to manufacturing defects.

Finally, the connector also enables the electrical connection between the printed circuit board and the motor, which is established at the tabs and ultimately at the pin of the connector.

Advantageously, the connector has three tabs. When there are at least three tabs, the head of the connector bears more uniformly against the printed circuit board. Alternatively, the connector may have two tabs. In this case, in order to maintain as effective an electrical connection as with three tabs, the cross section of each of the two tabs must be larger.

Further advantageous features of the apparatus that forms the subject matter of the invention are listed hereinbelow. Each of these features may be considered alone or in combination with the notable features defined hereinabove. Each of these features contributes, as appropriate, to solving specific technical problems defined earlier on in the description, to which problems the notable features defined hereinabove do not necessarily contribute. The latter may form the subject matter, as appropriate, of one or more divisional patent applications.

According to one embodiment of the invention, the head of the connector further comprises a planar central portion from which at least three branches, which respectively terminate in at least one tab, extend.

Advantageously, there are as many branches as there are tabs. Preferably, when there are three tabs, the head of the connector likewise has three branches. Alternatively, when there are two tabs, the connector head likewise has two branches. Alternatively, two distinct tabs may be positioned at the ends of each of the branches. The formation of branches makes it possible to limit the amount of material used while at the same time maintaining good efficiency for heat dissipation. The formation of branches also makes it possible to reduce the costs of manufacturing the connector on account of the smaller amount of material.

Alternatively, the planar central portion may form a solid metal cup, said cup having a planar main portion terminated at its periphery by a single curved portion, said portion regularly terminating in tabs that are preferably equidistant from one another. The planar metal cup has the same heat sink function, which in this case will be slightly more efficient on account of the greater amount of material.

According to one embodiment of the invention, each branch has at least one curved portion so as to orient each tab along its respective secondary longitudinal axis.

Advantageously, the curved portion forms an angle of approximately 90°, ±5°, with respect to the perpendicular plane of the planar central portion. The curved portion enables the tabs to be positioned in parallel and on the same side of the connector head as the pin of said connector. The curved portion reduces the fragility of the connector and promotes correct positioning of the tabs in the printed circuit board.

According to one embodiment of the invention, the curved portion comprises at least one bearing region configured to come into abutment against the printed circuit board when the connector is mounted on said circuit board.

Advantageously, the presence of at least one bearing region on the curved portion of the connector makes it possible to improve the correct positioning of said connector and to stabilize it before the tabs are soldered. According to a preferred embodiment, there are at least two bearing regions at the end of each of the branches, one on each side of the tab. Alternatively, the presence of a plurality of tabs at the end of each branch can vary the number of bearing regions. Alternatively, when the connector head forms a cup, at least one bearing region may be formed between two consecutive tabs.

Advantageously, the branches have an identical angular separation between them.

Advantageously, the angular separation between the branches is identical, thereby enabling the connector to be as balanced as possible for being positioned in the printed circuit board. This balancing will make it easier for the connector to be held unaided before and during soldering, which will assist in the manufacturing of the printed circuit board. For the connector, an identical angular separation between the branches also makes it possible to simplify manufacturing thereof and to reduce the time spent mounting it on the printed circuit board. More preferably, when the connector comprises three branches, the angular separation provided between two of the consecutive branches is 120°. The arrangement of the branches at 120° is particularly preferred, since it enables the connector to be placed more uniformly on the printed circuit board and enables more advantageous mechanics, including for the flow of electric current. Alternatively, when the connector has two branches, the angular separation between said branches is 180°.

Advantageously, the connector is made of a copper-based alloy.

Advantageously, the connector comprises a layer of nickel and a layer of tin.

Advantageously, the layer of tin is an external layer of said connector.

Advantageously, at least the tabs of the connector are made of copper.

Advantageously, the use of certain metallic materials makes soldering easier. Thus, copper or tin are particularly preferred materials. A copper-based alloy is understood to mean an alloy comprising at least 5% of copper in its composition. More preferably, a copper-based alloy is understood to mean an alloy comprising at least 50% by weight of copper in its total composition. Preferably, the tabs made entirely of copper enable the connector to be soldered to the printed circuit board more easily. Alternatively, the presence of an external layer of tin also enables the connector to be soldered to the printed circuit board more easily.

Advantageously, at least one of the branches has a length of between 5 mm and 7 mm, and a width of between 3.5 mm and 4.5 mm.

Advantageously, the length and width of the branches are designed to enable optimum heat dissipation.

Advantageously, all the branches of a single connector have identical dimensions. In particular, this enables it to be positioned on the printed circuit board more easily.

Advantageously, at least one of the tabs has a length of between 4 mm and 6 mm, and a width of between 1 mm and 5 mm.

Advantageously, the minimum length of the tabs must be greater than the thickness of the support of the printed circuit board on which the connector is to be mounted. Specifically, the length of the tabs must be designed independently of the soldering method chosen. Advantageously, the tab must be long enough to enable the connector to be held securely on the printed circuit board, and to enable the best possible electrical conduction between the printed circuit board and the connector. Thus, the shape, width and thickness of the tabs can vary according to the number of tabs positioned on the connector, so as to maintain optimum electrical conductivity.

More specifically, the electrical connection of the connector to the printed circuit board may be achieved by means of various techniques. Preferably, the techniques used are techniques for soldering the components, such as reflow soldering or wave soldering, for example. Soldering the tabs makes it possible to stabilize the connectors placed on the printed circuit board.

The preferred technique in the context of the invention is soldering. In this case, the solder paste is positioned between the printed circuit board and the branches of the connector, in contact with the orifices receiving one of the tabs. Preferably, two sections of solder paste are positioned to the side of each tab. In the case of wave soldering, soldering is carried out through capillary action on an opposite face of the printed circuit board to the face occupied by the head of the connector.

Advantageously, the pin has a length of between 20 mm and 30 mm, and a diameter of between 1.5 mm and 2.5 mm.

Advantageously, the pin must be long enough to pass through the printed circuit board and to enable a physical connection between the motor and the printed circuit board. Preferably, the diameter of the pin may be slightly smaller than the diameter of the orifice in which it is to be mounted, so as to enable it both to be fitted and to be restricted in terms of its movements. This fitting moreover makes it possible to have close contact between the connector and the printed circuit board. The diameter of the pin must also be sufficient to maintain a satisfactory physical connection between the motor and the printed circuit board, specifically in order to avoid any risk of breakage, which could prevent the motor from operating correctly. Additionally, the pin may be soldered to the printed circuit board.

According to one embodiment of the invention, the tabs of the connector all have an identical shape and identical dimensions.

Advantageously, the identical shape and identical dimensions between all the tabs enable the connector not only to be manufactured more easily but also to be installed on the printed circuit board more easily. Alternatively, the tabs may have a different shape and/or different dimensions.

According to one embodiment of the invention, at least one of the branches, referred to as distinct branch, has a greater length than the other branches.

Advantageously, the distinct branch is at least twice as long as the other branches, preferably at least three times as long as the other branches.

Advantageously, the fact that the connector has a distinct branch makes it possible to improve the efficiency during heat dissipation. Specifically, this distinct branch may advantageously be positioned close to the power components that produce the most heat, and thus improve its dissipation within the connector.

The invention also relates to a printed circuit board, said printed circuit board comprising at least one connector configured to enable an electrical connection to a motor and electrical and/or electronic components attached to said circuit board, said components comprising power components, the connector being according to the invention.

Advantageously, a printed circuit board comprising connectors according to the invention makes it possible to have a mechanical connection between the printed circuit board and the motor, while at the same time maintaining an electrical connection, at least via the tabs of said connector. Such a connector also makes it possible to improve the heat dissipation of the power components.

According to one embodiment of the invention, the printed circuit board comprises a first face to which the electrical and/or electronic components are attached, and a second face configured to be oriented toward the motor.

Advantageously, positioning the connectors close to the power components makes it possible to improve the heat dissipation of the latter and therefore to eliminate the potential harmful effects caused by excess heat, in particular in the long term. The heat produced by the components is transmitted to the connector heads situated on the first face of the printed circuit board. It then diffuses via the pin into the motor situated against the second face of said circuit board.

Advantageously, when the connector is mounted on the printed circuit board, the connector head is spaced apart from the printed circuit board so as to enable air to circulate between said head and the printed circuit board.

Advantageously, the distance between the connection head and the corresponding face of the printed circuit board makes it possible to have optimal heat dissipation by virtue of the presence of air. This distance also makes it possible to provide the connector with flexibility and therefore not to exert excessive mechanical stress between the soldering of the connector on the printed circuit board and the motor.

Advantageously, the distance between the central portion of the connector head and the printed circuit board is between 0.5 mm and 5 mm.

Advantageously, the distance between the central portion of the connection head and the corresponding face of the printed circuit board must not be too great, so as to limit the total thickness of the printed circuit board. Limiting the space occupied by said circuit board makes it possible to improve the miniaturization of the components and to save space in the design of the motor.

Advantageously, the circuit board comprises at least one set of orifices, the set of orifices comprising a central orifice configured to allow the pin of a connector to fit through it, and at least three orifices that are off-center with respect to the central orifice, each off-center orifice being configured to allow one of the tabs of said connector to protrude through it.

Advantageously, each set of orifices makes it possible to mount a connector on the printed circuit board. These orifices hold the connector in place before soldering.

Advantageously, the connector head is situated close to, or at a distance of at most 5 mm from, preferably of at most 2 mm from, the power components.

Advantageously, positioning the head close to the power components enables the best possible heat dissipation of said components.

According to one embodiment of the invention, at least one of the tabs protrudes through the printed circuit board by at least 1.2 mm so as to enable said tab to be soldered to or on the second face of the printed circuit board, and/or to or on the first face of the printed circuit board.

Advantageously, the fact that the tabs protrude enables them to be soldered more easily, in particular in the case of wave soldering. The length of the tabs also helps to hold the connector in position before soldering, by stabilizing the connector.

Advantageously, all the tabs of the connector are soldered to or on the second face of the printed circuit board, and/or to or on the first face of the printed circuit board.

Advantageously, the fact that all the tabs are soldered to the printed circuit board makes it possible to improve the force resistance of the connector and to limit the risks of breakage of the solder joints. This also improves the electrical connection of the connectors to the printed circuit board. The heat dissipation is also more efficient. Alternatively, at least one tab of each connector is soldered. Soldering just one tab reduces the costs of manufacturing the printed circuit board.

Advantageously, the circuit board comprises a plurality of connectors.

Advantageously, the plurality of connectors makes it possible to improve the mechanical connection, the electrical connection and the heat dissipation between the motor and the printed circuit board. Each connector may be assigned to a group of power components, and thus enable the heat dissipation of said group of components.

The invention also relates to a three-phase motor comprising at least one printed circuit board, the printed circuit board being according to the invention.

The three-phase motors according to the invention are more compact because they comprise fewer components, since the pins and the electrical connectors are combined. The service life of such motors is also increased by reducing the harmful effects caused by the heat, in the shorter or longer term, emitted by the power components. Improving heat dissipation reduces this problem.

Advantageously, the motor is a motor that has a power of between 400 and 500 W, the connector being according to the invention.

Advantageously, connectors with shorter branches make it possible to achieve good heat dissipation in low-power (between 400 W and 500 W) three-phase motors.

Advantageously, the motor is a motor that has a power of between 600 and 650 W, the connector being according to the invention.

Advantageously, connectors having a distinct longer branch enable better heat dissipation from power components to the motor. Specifically, since the longer branch is positioned close to the power components, they will enable more efficient heat recovery and better transmission to the pin. Thus, these connectors are particularly effective in higher-power (600 W to 650 W) three-phase motors.

### BRIEF DESCRIPTION OF THE FIGURES

Further advantages and features of the invention will become more clearly apparent upon reading the following description of a preferred embodiment, with reference to the appended drawings, which are provided by way of nonlimiting indicative examples and in which:

FIG. 1a is a perspective view of a connector according to a first embodiment of the invention, with a head of the connector oriented upward.

FIG. 1b is a perspective view of a connector from FIG. 1a, with the head of the connector oriented downward.

FIG. 2 is a bottom view of a printed circuit board mounted on a three-phase motor and comprising the connectors from FIGS. 1a and 1b.

FIG. 3a is an enlarged top view of the connector head from the preceding figures mounted on the printed circuit board.

FIG. 3b is an enlarged bottom view of the connector head from the preceding figures mounted on the printed circuit board.

FIG. 4 is a diagram showing a cross section of the connector from the preceding figures mounted on a printed circuit board.

FIG. 5 is a view of the connectors from the preceding figures mounted on the printed circuit board, with the solder paste for attaching each connector to said circuit board.

FIG. 6 is a perspective view of a connector according to a second embodiment of the invention, with a head of the connector oriented upward.

FIG. 7 is a bottom view of a printed circuit board comprising the connectors according to the second embodiment of the invention.

### DESCRIPTION OF THE EMBODIMENTS

As used herein, and unless stated otherwise, the use of the ordinal adjectives “first”, “second”, etc., to describe an object merely indicates that various occurrences of similar objects are being referred to and does not imply that the objects so described need to be in a given sequence, whether in time, space, order of rank, etc. “X and/or Y” means: X alone or Y alone or X+Y. In general, it will be appreciated that, in the various attached figures, the objects have been drawn arbitrarily to make the drawings easier to read. In the remainder of the description, the term “longitudinally” is understood to mean the direction of the length of the pin and/or the tabs.

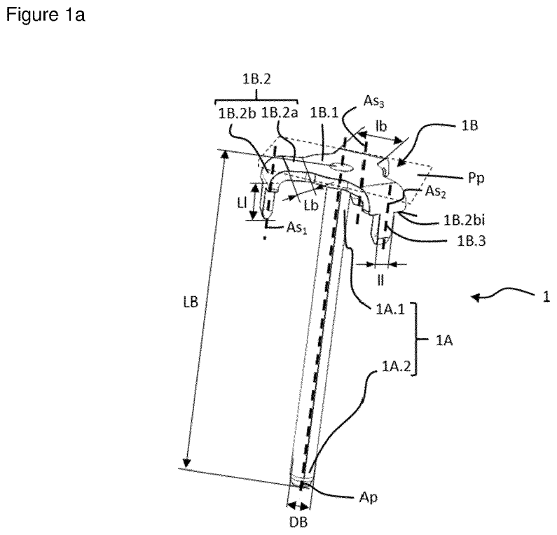

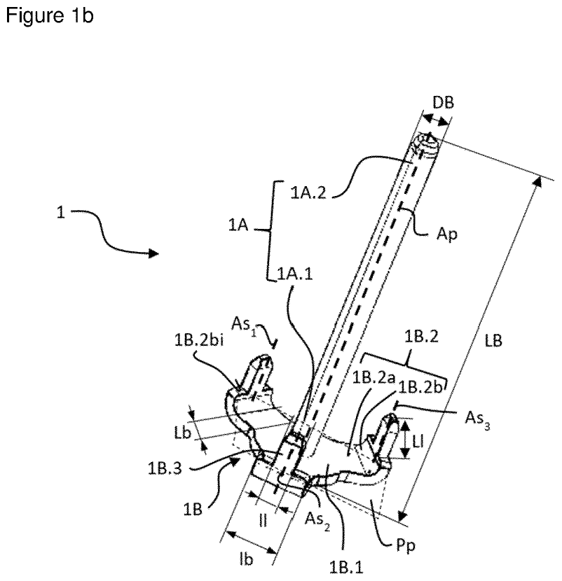

FIGS. 1a and 1b show two views of a connector according to a first embodiment of the invention.

A connector 1 according to a first embodiment of the invention comprises a pin 1A that extends longitudinally along a main axis Ap of said pin 1A, “the main axis” being the axis passing through its center and extending longitudinally to the pin 1A. The pin 1A has a length LB of between 20 mm and 30 mm, more preferably between 28 mm and 30 mm, and a diameter DB of between 1.5 mm and 2.5 mm, more preferably of between 1.7 mm and 2.3 mm. The pin 1A also comprises a first end 1A.1 from which a connector 1 head 1B extends, and a second end 1A.2 remaining free.

In this embodiment of the invention, the head 1B of the connector 1 extends along a plane Pp that is substantially perpendicular to the main axis Ap of the pin 1A. A “plane Pp that is substantially perpendicular” is a plane extending perpendicular to the main axis Ap of the pin 1A, i.e. a plane extending approximately at 90° to the main axis Ap, with a possible deviation of plus or minus 5°. This deviation may be due to the manufacturing and/or mounting variations of the connectors 1. Preferably, the head 1B of the connector 1 comprises a planar central portion 1B.1 that extends along the substantially perpendicular plane Pp. A “planar central portion” is understood to mean the portion of the head 1B of the connector 1 positioned close to the first end 1A.1 of the pin 1A. In these figures, the planar central portion 1B.1 has a substantially circular shape. However, it may have different shapes that are not shown in these figures, including that of a solid cup.

The planar central portion 1B.1 of the head 1B of the connector 1 may be extended by at least three branches 1B.2. Preferably, each branch 1B.2 has a length Lb of between 2 mm and 5 mm, more preferably between 1.5 mm and 3.5 mm. Preferably, each branch 1B.2 also has a width Ib of between 1 mm and 5 mm, more preferably between 3 mm and 4 mm. The branches 1B.2 also have an angular separation between them that is preferably identical. “Angular separation” is understood to mean the angle between two consecutive branches 1B.2 of the connector 1 head 1B. In a preferred embodiment, when the connector 1 head 1B comprises three branches 1B.2, the angular separation between two consecutive branches 1B.2 is approximately 120°. Alternatively, at least two branches 1B.2 may extend from the planar central portion 1B.1 of the head 1B of the connector 1. Thus, if the head 1B of the connector 1 comprises just two branches 1B.2, the angular separation between the branches 1B.2 is approximately 180°. Alternatively, the angular separation between two consecutive branches 1B.2 may vary.

Each of the branches 1B.2 may comprise a substantially planar portion 1B.2a in continuity with the planar central portion 1B.1 of the connector 1 head 1B, the substantially planar portion 1B.2a extending in a plane Pp that is substantially perpendicular to the main axis Ap of the pin 1A.

The branch 1B.2 further comprises a curved portion 1B.2b in continuity with the substantially planar portion 1B.2a and at the opposite end of the planar central portion 1B.1. Each curved portion 1B.2b also has at least one bearing region 1B.2bi, the function of which will be explained below. According to a preferred embodiment, there are at least two bearing regions 1B.2bi at the end of each branch 1B.2. Alternatively, when the planar central portion 1B.1 forms a solid cup, said portion 1B.1 terminates at its periphery in a single curved portion (not shown in these figures).

The head 1B of the connector 1 further comprises at least three tabs 1B.3, each of which extends along a secondary longitudinal axis (As₁, As₂, As₃) parallel to the main axis Ap of the pin 1A. “Secondary longitudinal axis” is understood to mean a distinct axis parallel to the main axis Ap of the pin 1A. Thus, a secondary longitudinal axis (As₁, As₂, As₃) passes through each of the tabs 1B.3 and is distinct from the secondary longitudinal axes (As₁, As₂, As₃) of the other tabs 1B.3.

Alternatively, two tabs 1B.3 may extend from the connector 1 head 1B. The tabs 1B.3 and the pin 1A of the connector 1 all extend on the same side of the head 1B of the connector 1.

Preferably, the tabs 1B.3 are positioned at the end of the branch 1B.2, each branch 1B.2 preferably supporting a single tab 1B.3. When the branch 1B.2 supports a single tab 1B.3, the tab 1B.3 preferably extends from the middle of the curved portion 1B.2b, so as to form two bearing regions 1B.2bi, one on each side of said tab 1B.3. The orientation of the curved portion 1B.2b, the free end of which is oriented on the same side as the pin 1A of the connector 1, enables the tabs 1B.3 to be correctly positioned on the same side of the head 1B of the connector 1. The curved portion 1B.2b of each branch 1B.2 makes it possible to orient each tab 1B.3 along its secondary longitudinal axis (As₁, As₂, As₃). Alternatively, each branch 1B.2 may support a plurality of tabs 1B.3. Alternatively, when the planar central portion 1B.1 forms a solid cup, the tabs 1B.3 can be positioned in continuity with the curved portion and preferably equidistantly from one another (variant not shown in these figures).

Preferably, each tab 1B.3 has a length Ll of between 2.8 mm and 5 mm, more preferably between 2.8 mm and 3.2 mm, and a width Il of between 1 mm and 5 mm, more preferably between 1.5 mm and 4 mm.

Advantageously, the tabs 1B.3 of a single connector 1 all have an identical shape and identical dimensions. Alternatively, the tabs 1B.3 of a single connector 1 may have different shapes and dimensions. Thus, the tabs 1B.3 may have a round, rectangular or cuboidal cross section, depending on the size of the connector 1 and/or the desired function.

The connector 1 is made of metal, so as to be able to exert a heat sink effect. Advantageously, the connector 1 is made from a copper-based alloy. A copper-based alloy is understood to mean an alloy that comprises a minimum percentage of copper of at least 5% by weight, and more preferably of at least 50% by weight. Alternatively, only the tabs 1B.3 are made of copper, the rest of the connector 1 being made from various metallic materials.

Alternatively, the connector 1 may be manufactured from different materials. The connector 1 may, for example, consist of a layer of nickel covered by a layer of tin. Advantageously, the layer of tin is an external layer of the connector 1.

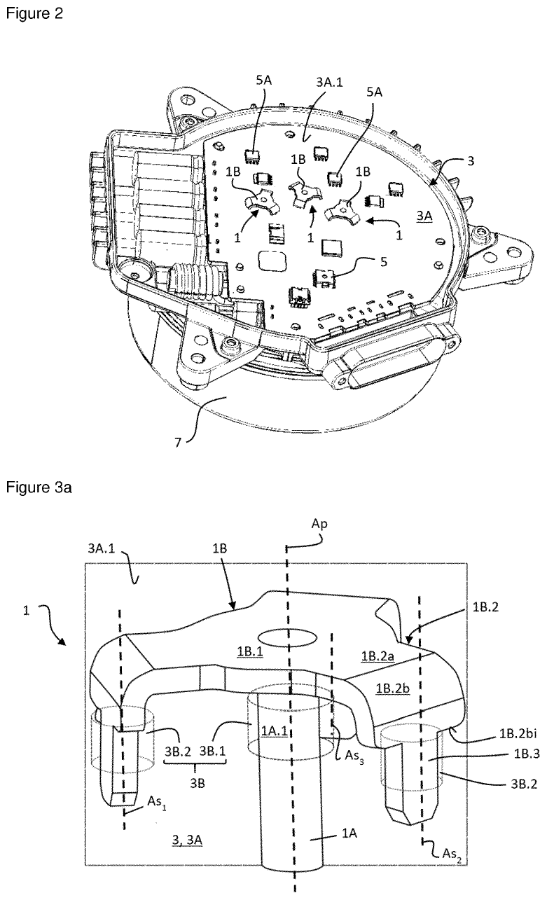

FIG. 2 shows a view of three connectors according to the first embodiment of the invention mounted on a printed circuit board.

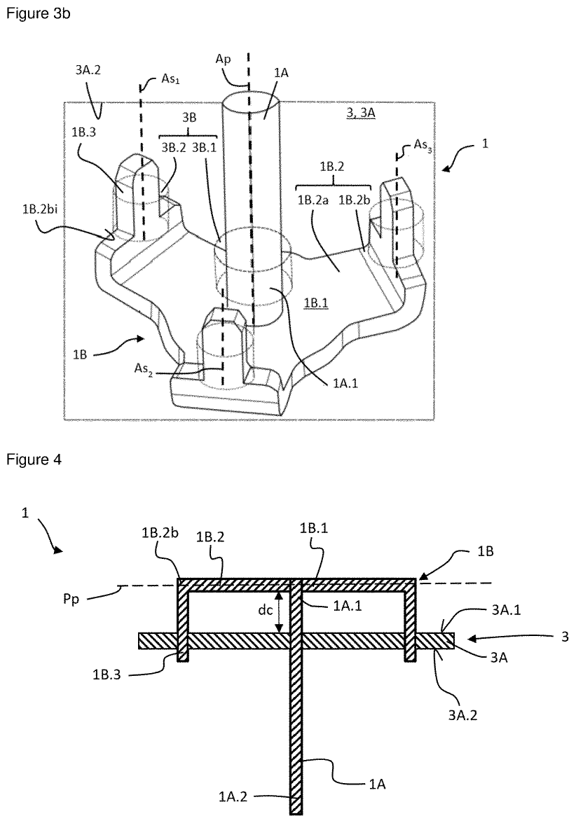

The one or more connectors 1 according to the invention are therefore configured to be mounted on a printed circuit board 3. The printed circuit board 3 according to the invention comprises at least one support 3A, generally manufactured from a plastics material, said support 3A comprising a first face 3A.1 and a second face (the second face not being visible in FIGS. 3b and 4). Electrical and/or electronic components 5 are attached to the first face 3A.1 of the support 3A. Some of these components 5 are power components 5A, i.e. components 5A that produce high heat, this heat preferably having to be diffused so as to avoid degrading the various components 5 of the printed circuit board 3. The support 3A also has layers of copper enabling the components (5; 5A) to be electrically connected to one another. For the sake of simplicity, these layers are not shown in the drawings. Advantageously, the printed circuit board 3 according to the invention comprises a plurality of connectors 1.

These connectors 1 are therefore preferably positioned close to the power components 5A, in order to best perform their heat sink function. Preferably, the connectors 1 are positioned less than 5 mm, more preferably at most 2 mm, from the power components 5A from which they must dissipate heat. The heat will thus be diffused from the connector 1 head 1B toward the pin (not visible in this figure) integrated in a motor 7.

The connectors 1 are also intended to enable an electrical connection to the motor 7. Thus, the printed circuit board 3 is positioned against the motor 7 and will enable the various functions of said motor 7 to be activated. More particularly, it is the second face of the printed circuit board 3 that is oriented toward the motor 7. This motor 7 is advantageously a three-phase motor 7, which can be used in particular for operating a motor vehicle fan (the fan not being shown in these figures). Moreover, a mechanical connection between the printed circuit board 3 and the motor 7 is enabled by virtue of the pins of the connector 1 (said pins not being visible in this figure). Preferably, when the connectors 1 are according to the first embodiment of the invention, they are particularly effective in a three-phase motor 7 having a power of between 400 W and 500 W, since they combine good heat dissipation with a good electrical and mechanical connection.

FIGS. 3a and 3b show enlarged views of the connector head according to the first embodiment of the invention, mounted on the printed circuit board, which is shown as transparent.

In these two figures, the pin 1A and the tabs 1B.3 of the connector 1 are configured to pass through the printed circuit board 3, so that the connector 1 can form the heat sink for the power components (these components not being shown in FIGS. 3a and 3b). The passage of the tabs 1B.3 and the pin 1A is permitted by virtue of the presence of a set of orifices 3B provided for this purpose in the printed circuit board 3.

A set of orifices 3B is provided for each connector 1 to be installed on the printed circuit board 3. Thus, each set of orifices 3B comprises a central orifice 3B.1 and at least three orifices 3B.2 that are off-center with respect to said central orifice 3B.1. The central orifice 3B.1 more specifically enables the pin 1A of the connector 1 to be fitted. Each of the off-center orifices 3B.2 is configured to allow one of the tabs 1B.3 of the corresponding connector 1 to protrude through it. Alternatively, if two tabs 1B.3 are provided, only two off-center orifices 3B.2 will be provided close to the central orifice 3B.1.

In FIGS. 3a and 3b, the connector 1 head 1B is positioned on the first face 3A.1 (visible in FIG. 3a) of the printed circuit board 3, the pin 1A and at least one of the tabs 1B.3 protruding toward the second face 3A.2 (visible in FIG. 3b) of said circuit board 3. Advantageously, at least one of the tabs 1B.3 protrudes through the printed circuit board 3. The at least one of the tabs 1B.3 advantageously protrudes by at least 1.2 mm. Preferably, all the tabs 1B.3 protrude.

Thus, when the connector 1 is mounted on the printed circuit board 3, the one or more bearing regions 1B.2bi of the branches 1B.2 are configured to come into abutment against said circuit board 3, and more particularly against the first face 3A.1 of the printed circuit board 3. This configuration improves the stability of the connector 1 on the printed circuit board 3.

FIG. 4 shows a cross-sectional view of the connector according to the first embodiment of the invention, mounted on the printed circuit board.

When the connector 1 is mounted on the printed circuit board 3, the head 1B of said connector 1 is positioned at a distance dc from said circuit board 3, and more particularly at a distance de from the first face 3A.1 of said circuit board 3. This distance de between the planar central portion 1B.1 of the head 1B of the connector 1 and the printed circuit board 3 is preferably between 0.5 mm and 5 mm, and more preferably between 2 mm and 4 mm.

The minimum distance de enables air to circulate between the connector 1 head 1B and the printed circuit board 3, and therefore enables the heat dissipation of the power components situated near the connector 1 (said components not being visible in FIG. 4). A maximum distance de makes it possible to limit the total thickness of the printed circuit board 3.

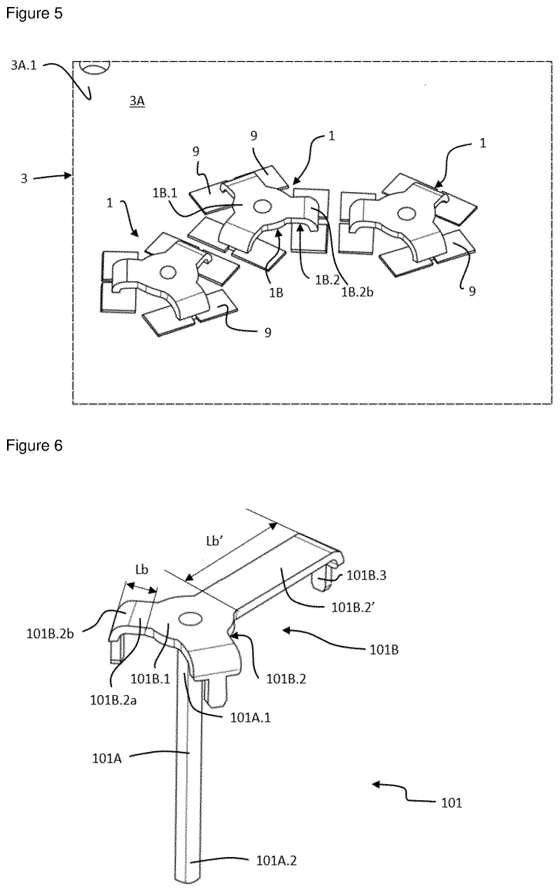

FIG. 5 shows a view of the connectors according to a first embodiment of the invention, mounted on the printed circuit board, and before soldering.

Various methods may be used to attach the connectors 1 to the printed circuit board 3. The preferred method is soldering, and more preferably the wave soldering method. Alternatively, other methods known to a person skilled in the art may be envisioned.

Preferably, at least one of the tabs (the tabs not being visible in this figure) of each connector 1 is attached to the printed circuit board 3 by soldering. More preferably, in order to enable better force resistance, the three tabs are attached to the printed circuit board 3 by soldering.

In order to carry out the soldering, at least two portions of solder paste 9 per tab are positioned on the first face 3A.1 of the printed circuit board 3. Preferably, these two portions 9 of solder paste are positioned on each side of a tab. During soldering, the solder paste 9 will be introduced by capillary action into the orifice (said orifice not being visible in this figure) so as to solder the corresponding tab to the printed circuit board 3. The two sections of solder paste 9 enable the soldering to surround the entire tab. Preferably, the volume of solder paste 9 desired per tab is between 5 mm³ and 7 mm³, and more preferably, the volume is approximately 6mm³. Preferably, the material chosen for carrying out the soldering is copper.

Additionally, soldering may also be provided around the pin of each connector 1 (the pin not being visible in this figure).

This type of soldering allows for better reliability and better repeatability of the soldering process. Soldering is more efficient, more durable and able to be carried out in a more controlled manner.

Alternatively, soldering can be carried out on the second face of the printed circuit board 3 (the second face not being visible in this figure). In this case, the fact that one of the tabs protrudes is important for carrying out soldering correctly.

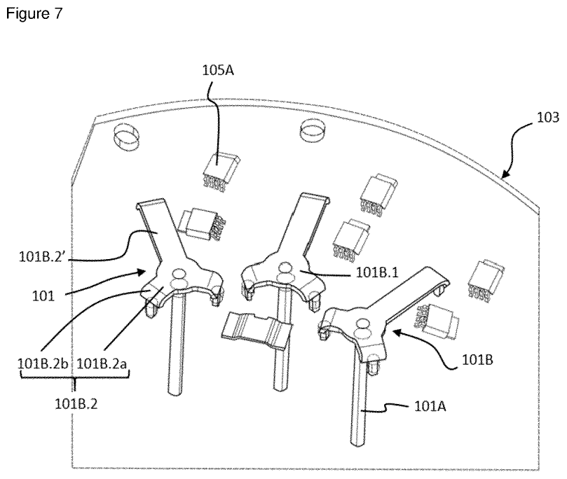

FIGS. 6 and 7 show a connector according to a second embodiment of the invention, by itself or mounted on a printed circuit board. These figures repeat the numbering in preceding FIGS. 1 to 5 for identical or similar elements, but with the numbering being incremented by 100. Reference is also moreover made to the description of these elements that was given with regard to the first embodiment of the invention.

The general features of a connector 101 are similar to those previously described in the first embodiment. Thus, the connector 101 according to the second embodiment of the invention also comprises a pin 101A and a connector 101 head 101B, said head 101B comprising a planar central portion 101B.1 and branches 101B.2 on which tabs 101B.3 are positioned. The first and second ends 101A.1, 101A.2 of the pin 101A are also visible.

Thus, each branch 101B.2 comprises a substantially planar portion 101B.2a and a curved portion 101B.2b as described above. However, one of the branches 101B.2 of the connector 101 is a distinct branch 101B.2′, which has a length Lb′ that is greater than the length Lb of the other branches 101B.2. Advantageously, the length Lb′ is at least twice as great, more preferably three times as great, as the length Lb of the other branches 101B.2. Thus, the length Lb′ is preferably between 2 mm and 20 mm. Alternatively, the connector 101 head 101B may comprise more than one distinct branch 101B.2′.

Thus, as can be seen in FIG. 7, the distinct branch 101B.2′ may extend close to the power components 105A mounted on the printed circuit board 103, and the connectors 101 of which are to dissipate heat. This type of connector 101 is particularly effective in three-phase motors having a significantly higher power than the abovementioned motors (said motor not being shown in FIG. 7). In particular, motors having a power from 600 W to 650 W could benefit from such connectors 101. Specifically, the power components 105A of these motors produce more heat because they are more powerful. In addition, a more efficient connector 101 could improve heat dissipation and reduce the damage caused by the heat emitted.

The arrangement of the various elements and/or means and/or steps of the invention, in the embodiments described hereinabove, must not be interpreted as demanding such an arrangement in all implementations. In any case, it will be appreciated that various modifications may be made to these elements and/or means and/or steps without departing from the spirit and scope of the invention.

Furthermore, one or more of the features set out in just one embodiment may be combined with one or more other features set out in just one other embodiment. Likewise, one or more features set out in just one embodiment may be generalized to the other embodiments, even if this or these features are described only in combination with other features.

The use of the verbs “have”, “comprise” or “include” and conjugated forms thereof does not exclude the presence of elements or steps other than those stated in a claim.

1. A connector for a printed circuit board, the connector is configured to enable an electrical connection to a motor, the connector comprising:
a pin extending longitudinally along a main axis; and
a connector head, which is attached to one end of the pin and extends in a plane that is perpendicular to said main axis of the pin, the head comprising at least three tabs each extending along a secondary longitudinal axis parallel to the main axis of the pin,
wherein the tabs all extend from the same side of the connector head so that said tabs, as well as the pin, are configured to pass through the printed circuit board,
wherein the connector is made of a metal so as to form a heat sink for the printed circuit board.

2. The connector as claimed in claim 1, wherein the head of the connector further comprises a planar central portion from which at least three branches, which respectively terminate in at least one tab, extend.

3. The connector as claimed in claim 2, wherein each branch has at least one curved portion so as to orient each tab along its respective secondary longitudinal axis.

4. The connector as claimed in claim 3, wherein the curved portion comprises at least one bearing region configured to come into abutment against the printed circuit board when the connector is mounted on said circuit board.

5. The connector as claimed in claim 1, wherein the tabs of the connector all have an identical shape and identical dimensions.

6. The connector as claimed in claim 2, wherein at least one of the branches, referred to as distinct branch, has a greater length than the other branches.

7. A printed circuit board, said printed circuit board comprising at least one connector configured to enable an electrical connection to a motor and electrical and/or electronic components attached to said circuit board,
wherein said components comprising power components,
wherein the connector is as claimed in claim 1.

8. The printed circuit board as claimed in claim 7, wherein the printed circuit board comprises:
a first face to which the electrical and/or electronic components are attached; and
a second face configured to be oriented toward the motor.

9. The printed circuit board as claimed in claim 8, wherein at least one of the tabs protrudes through the printed circuit board by at least 1.2 mm so said tab is soldered to or on the second face of the printed circuit board, and/or to or on the first face of the printed circuit board.

10. A three-phase motor comprising at least one printed circuit board, wherein the printed circuit board is as claimed in claim 7.
